(19) United States
(12) Patent Application Publication
(10) Pub. No.: US 2026/0190242 A1
(43) Pub. Date: Jul. 2, 2026

(54) MANUFACTURING METHOD OF VIA HOLES

(71) Applicant: Absolics Inc., Covington, GA (US)

(72) Inventors: Chun Jae LEE, Covington, GA (US); Tae Kyoung KIM, Covington, GA (US)

(73) Assignee: Absolics Inc., Covington, GA (US)

(21) Appl. No.: 19/424,166

(22) Filed: Dec. 18, 2025

Related U.S. Application Data
(60) Provisional application No. 63/740,334, filed on Dec. 31, 2024.

(51) Int. Cl. H05K 3/00; H05K 1/02

(52) U.S. Cl. CPC H05K 3/0035; H05K 1/0269; H05K 3/0055

(57) ABSTRACT

An embodiment provides a method of manufacturing via holes, comprising: a first processing operation of applying a long-wavelength laser to a predetermined position of a workpiece to form a first hole; and a second processing operation of applying a short-wavelength laser to the position where the first hole has been formed to form a second hole and thereby form a via hole. The workpiece comprises an insulating layer disposed over a core substrate, and the via hole is formed in the insulating layer.

### CROSS-REFERENCE TO RELATED APPLICATION

This application claims the priority of U.S. Provisional Patent Application No. 63/740,334, filed December 31, 2024, the entire disclosures of which are incorporated herein by reference for all purposes.

### BACKGROUND

### Technical Field

An embodiment relates to a manufacturing method of via holes, and pertains to a method by which even deep via holes may be reliably manufactured with excellent accuracy.

### Background Art

Laser drilling refers to forming small holes and special via holes for interlayer connection in a multilayer substrate by using laser light.

This laser-drilling technique emerged as one of the processing methods for via holes corresponding to interlayer connection paths in multilayer substrates, in order to resolve limits to circuit miniaturization and increased machining costs associated with the use of mechanical drills.

By the laser-drilling technique, via holes in multilayer substrates can be formed more finely than by conventional mechanical machining, and processing costs are greatly reduced; however, other problems have arisen.

Currently, in manufacturing multilayer substrates using laser drilling, when a hole is formed, a hole-cleaning process is required at the end to remove fine foreign substances generated inside the hole during via-hole formation.

If perfect cleaning is not achieved, smear and plating defects during subsequent copper electroplating may occur. Moreover, because a laser shot for cleaning must be performed again after forming a hole of the desired size, a problem may arise in that a hole having a diameter larger than the design value is formed. To prevent this, it is necessary to design and machine the hole size in advance while taking the final shot into account, which can cause inconveniences such as an increase in unit man-hours.

Related prior art includes Korean Patent No. 10-0730782 and Korean Patent Publication No. 10-2012-0096699.

### SUMMARY

A manufacturing method of via holes according to an embodiment includes: a first processing operation of forming a first hole by applying a long-wavelength laser to a predetermined position of a workpiece; and a second processing operation of forming a second hole by applying a short-wavelength laser to the position where the first hole has been formed, thereby forming a via hole.

The workpiece includes an insulating layer disposed over a core substrate, and the via hole is formed in the insulating layer.

In the first processing operation, a surface of the workpiece may be the insulating layer, or a laminate in which a polymer film is stacked over the insulating layer.

The manufacturing method of via holes may further include a position-correction operation between the first processing operation and the second processing operation.

The position-correction operation may be an operation of checking an alignment mark, an overlay coupon pattern, or both disposed on the substrate, and matching a position of the first hole in the first processing operation with a center position of the second hole to be formed in the second processing operation.

A distance from a surface of the insulating layer to a bottom of the second hole may be 60 µm or more.

A distance from the surface of the insulating layer to a bottom of the first hole may be within 40 µm.

A processing-protection layer may be further disposed over the insulating layer, and the processing-protection layer may be the polymer film.

A step (S) may be present at a boundary between the first hole and the second hole.

The manufacturing method may further include an insulating-layer forming operation before the first processing operation.

The insulating-layer forming operation may include: disposing, over the core substrate, a laminate of an insulating material and a polymer film; under reduced-pressure lamination conditions, allowing the insulating material to flow under pressure applied by the polymer film so that the insulating material is redistributed into voids inside the core substrate and over a surface thereof; and semi-curing or curing the insulating material; thereby providing the workpiece in which an insulating layer is disposed over the core substrate and the polymer film is disposed over the insulating layer.

The manufacturing method may further include a cleaning operation after the second processing operation.

The cleaning operation may include a process of removing particulate by-products or smear generated during the formation of the first and second holes.

The cleaning operation may include: a desmear process of removing the particulate by-products or smear by applying plasma or a desmear chemical solution; and a protection-layer removal process of removing the processing-protection layer from the substrate that has undergone the desmear process.

### BRIEF DESCRIPTION OF DRAWINGS

FIGS. 1 and 2 are conceptual cross-sectional views illustrating a method of manufacturing via holes according to an embodiment.

FIG. 3 is a conceptual cross-sectional view illustrating electrodes formed in a via hole formed according to an embodiment.

FIG. 4 is a top-view photograph of a via hole formed according to an embodiment, wherein the upper image shows the first hole and the lower image shows the second hole.

### DETAILED DESCRIPTION

Hereinafter, embodiments will be described in detail with reference to the accompanying drawings so that those skilled in the art can readily carry out the invention. However, the invention may be embodied in various different forms and is not limited to the embodiments described herein. Throughout the specification, like reference numerals refer to like parts.

Throughout this specification, the term “combinations thereof” included in a Markush-type expression means one or more mixtures or combinations selected from the group of components recited in the Markush-type expression, and means that one or more selected from the group of the components are comprised.

Throughout this specification, terms such as “first,” “second,” or “A,” “B” are used to distinguish identical terms from one another. In addition, unless otherwise clearly indicated by the context, the singular includes the plural.

In this specification, “~ group” may mean that a compound includes a compound corresponding to “~” or a derivative of “~” in the compound.

In this specification, the expression that B is positioned over A means that B is positioned directly in contact over A or B is positioned over A with another layer interposed therebetween, and it must not be construed as being limited to B being in contact with the surface of A.

In this specification, the expression that A is connected with B means that A and B are directly connected or connected through another component interposed between A and B, and unless otherwise specified, it must not be construed as being limited to A and B being directly connected.

In this specification, a singular form, unless otherwise specified, is construed to include a singular or plural as interpreted in context.

In this specification, the shapes, relative sizes, angles, etc. of the respective elements in the drawings are illustrative and may be exaggerated for purposes of description, and the scope of rights must not be construed as being limited to the drawings.

In this specification, that A and B are adjacent means that A and B are in contact with each other, or that A and B are not in contact but are positioned close to each other. Unless otherwise specified, the expression that A and B are adjacent must not be construed as being limited to A and B being in contact.

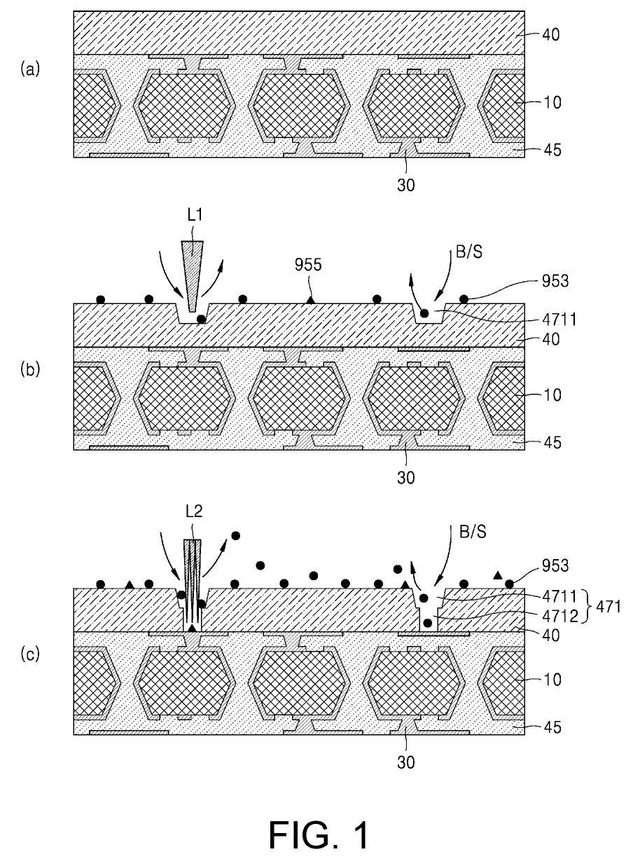

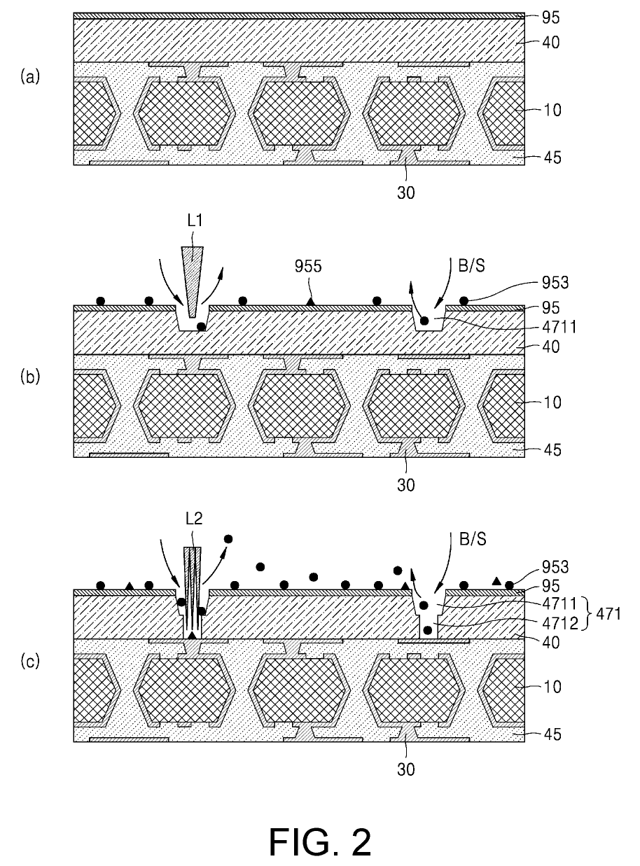

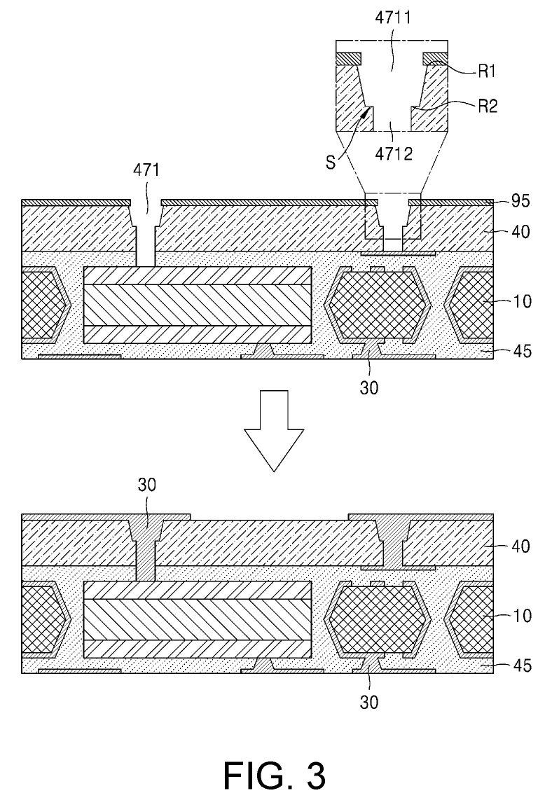

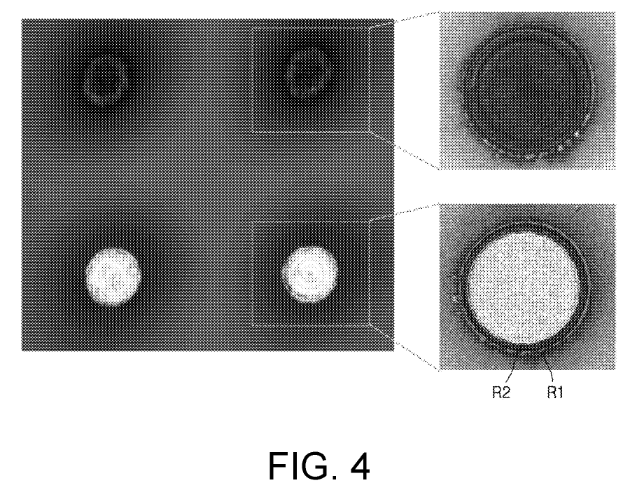

FIGS. 1 and 2 are conceptual cross-sectional views respectively illustrating a method of manufacturing via holes according to an embodiment, and FIG. 3 is a conceptual cross-sectional view illustrating electrodes formed in a via hole formed according to an embodiment. FIG. 4 is a top-view photograph of a via hole formed according to an embodiment, in which an upper image shows a first hole and a lower image shows a second hole. Hereinafter, an embodiment will be described in more detail with reference to FIGS. 1 to 4.

A method of manufacturing via holes according to an embodiment comprises a first processing operation and a second processing operation, and forms a via hole (471) in an insulating layer (40).

The first processing operation is an operation of forming a first hole (4711) by applying a CO₂ laser (L1) to a predetermined position of a workpiece.

The via hole (471) is formed in the insulating layer (40).

Via holes having a depth within about 30 µm may be manufactured by laser processing. However, via holes deeper than this are difficult to form by a conventional simple laser process, and even if formed, problems may occur such as the opening becoming excessively large or damage being caused to other portions of the substrate.

In the embodiment, deep via holes are efficiently and reliably formed by applying a long-wavelength laser and a short-wavelength laser respectively in the first processing operation and the second processing operation.

The long-wavelength laser (L1) may be, for example, a CO₂ laser or a CO laser. In the following description, a CO₂ laser is explained as a representative example of a long-wavelength laser; however, a CO laser is not excluded and may be applied in place of the CO₂ laser.

The short-wavelength laser (L2) may be, for example, a UV laser.

The workpiece may be one in which an insulating layer (40) is disposed over a core substrate (10) ((a) of FIG. 1).

The workpiece may be one in which an insulating layer (40) and a polymer film (95) are disposed over a core substrate (10) ((a) of FIG. 2).

In the first processing operation, a surface of the workpiece may be the insulating layer (40), or a laminate in which the polymer film (95) is stacked over the insulating layer (40).

A processing-protection layer is further disposed over the insulating layer (40), and the processing-protection layer may be the polymer film (95).

For example, the polymer film (95) may be a film whose organic layer comprises a polyimide resin, a polyethylene naphthalate resin, or a polyethylene terephthalate resin. For example, the polymer film (95) may be a PET film.

The polymer film (95) may have a thickness of 20 µm or more, 30 µm or more, 40 µm or more, or 50 µm or more. The thickness may be 500 µm or less, 450 µm or less, 400 µm or less, 350 µm or less, 300 µm or less, 250 µm or less, 200 µm or less, or 150 µm or less.

A long-wavelength laser (e.g., CO₂ laser, CO laser) applies a relatively long wavelength and can remove the insulating layer and the polymer film together ((b) of FIG. 1, (b) of FIG. 2). For example, the long-wavelength laser may apply a long wavelength of about 9.4 µm or more. The long wavelength may be about 9.4 µm or more and about 12 µm or less.

However, when forming a deep via hole by a long-wavelength laser, there is a drawback in that damage may be caused to a lower portion of the via hole due to thermal shock, etc., and as the depth increases, the number of required shots increases and the size of the opening hole may rapidly increase.

In the embodiment, the long-wavelength laser may be applied up to a depth within about 40 µm, and thereafter another laser is applied in the second processing operation.

That is, a distance from a surface of the insulating layer (40) to a bottom of the first hole (4711) may be within 40 µm. The distance may be 10 µm or more, 15 µm or more, 20 µm or more, 25 µm or more, or 30 µm or more. The distance may be 40 µm or less, or 30 µm or less.

When via holes are formed by a long-wavelength laser, a relatively flat bottom surface of the via hole can be formed.

During the process of forming a via hole by a long-wavelength laser, the removed insulating layer, etc. may become processing by-products and form particulate by-products or smear.

If such particulate by-products remain inside the via hole, subsequent cleaning processes may become difficult, and disconnection and the like may occur in subsequent processes. Therefore, in order to facilitate via formation and efficiently proceed with subsequent processes, blowing and/or suction (B/S) may be performed simultaneously with or after laser irradiation. For example, blowing may apply a gas such as CDA (Clean Dry Air) or N₂, but is not limited thereto.

The particulate by-products or smear may partially remain inside the via hole and may be deposited over the insulating layer.

The second processing operation is an operation of forming a second hole (4712) by applying a short-wavelength laser (L2) to the position where the first hole (4711) has been formed, thereby forming the via hole (471) ((c) of FIG. 1, (c) of FIG. 2).

The short-wavelength laser may have a pulse width of 400 nm or less.

The pulse width of the short-wavelength laser may be 400 nm or less, 350 nm or less, 340 nm or less, 330 nm or less, 320 nm or less, 310 nm or less, 300 nm or less, 290 nm or less, 280 nm or less, 270 nm or less, 260 nm or less, or 250 nm or less. The pulse width of the short-wavelength laser may be 100 nm or more.

The short-wavelength laser may have a pulse energy of 10 mJ or more, 15 mJ or more, 20 mJ or more, 25 mJ or more, 30 mJ or more, 35 mJ or more, or 40 mJ or more. The pulse energy may be 1 J or less. By applying such pulse energy, the insulating layer and the like can be removed more efficiently.

A UV laser may have a pulse repetition rate of 10 Hz or more, 50 Hz or more, 100 Hz or more, 300 Hz or more, 600 Hz or more, 900 Hz or more, 1,000 Hz or more, 2,000 Hz or more, 3,000 Hz or more, 4,000 Hz or more, or 5,000 Hz or more. The pulse repetition rate may be 10 kHz or less.

The short-wavelength laser may have a pulse repetition rate of 5 kHz or more and 1 MHz or less and an energy of 1 mJ or less.

The short-wavelength laser may have a pulse repetition rate of 1 Hz or more and 5 kHz or less and a high energy of 1 J or less.

Such a short-wavelength laser allows machining into a shape having resolution while applying a relatively high repetition rate and relatively high energy at the same time.

In particular, when the depth is 20 µm or less, it is possible to reliably implement a via having a diameter of 20 µm or less.

A short-wavelength laser can form a via hole deeply without expanding an opening size. In addition, unlike a long-wavelength laser, a short-wavelength laser can relatively reduce damage to glass or metal, thereby aiding the formation of a highly reliable via hole.

The short-wavelength laser forms the second hole (4712), and its depth may be about 10 µm or more, 15 µm or more, 20 µm or more, 25 µm or more, 30 µm or more, 35 µm or more, or 40 µm or more. The depth may be 70 µm or less, 65 µm or less, 60 µm or less, 55 µm or less, or 50 µm or less.

When a via hole is formed by such a process, a distance from the surface of the insulating layer (40) to the bottom of the second hole (4712) may be 60 µm or more, 65 µm or more, 70 µm or more, 75 µm or more, 80 µm or more, 85 µm or more, 90 µm or more, or 100 µm or more. The distance may be 200 µm or less, 180 µm or less, 160 µm or less, 140 µm or less, 120 µm or less, or 110 µm or less. This is deeper than a conventional via-hole depth, and such a via hole may assist efficient via-hole formation and redistribution-layer formation.

The depth of the via hole is the sum of the depths of the first hole and the second hole.

The depth of the first hole may be 20% or more, 25% or more, or 30% or more of the depth of the via hole. In addition, the depth of the first hole may be 70% or less, 65% or less, 60% or less, 55% or less, or 50% or less of the depth of the via hole. In such cases, via-hole formation may proceed more efficiently and with higher accuracy.

A position-correction operation may further be included between the first processing operation and the second processing operation.

The position-correction operation is an operation of checking an alignment mark (not shown), an overlay coupon pattern (not shown), or both disposed on the substrate, and matching the position of the first hole (4711) in the first processing operation with the center position of the second hole (4712) to be formed in the second processing operation.

The position-correction operation is an operation that can improve the reliability of via-hole formation.

Although it is exemplified that the position-correction operation is performed between the first processing operation and the second processing operation, when multiple laser irradiations are performed in each operation, the position-correction operation may additionally be applied, if necessary, also between respective laser irradiations.

A step (S) may be formed at a boundary between the first hole (4711) and the second hole (4712) ((a) of FIG. 3). The step may occur due to a difference in opening size formed according to the application of the two different lasers. When viewed in cross-section, the step is observed as a step.

When viewed from above, the via hole can be observed in a form in which two rings are arranged side by side (see FIG. 4). Specifically, referring to FIG. 4, which is a top-view photograph of a via hole after the first processing operation and after the first and second processing operations, there is an appearance difference between these two holes, and in particular, the second-hole opening (R2) is disposed inward compared with the first-hole opening (R1).

The position-correction operation may be performed once again after forming the second hole. At this time, the alignment mark (not shown), the overlay coupon pattern (not shown), etc. may be checked. Alternatively, position correction may be performed by checking the arrangement of R1 and R2, a difference in distance between them according to the direction of the circles, etc.

The manufacturing method may further comprise a cleaning operation after the second processing operation.

The cleaning operation is an operation of removing particulate by-products (953) or smear (955) generated during the formation of the first hole (4711) and the formation of the second hole (4712).

The particulate by-products (953) or smear (955) generated during the formation of the first hole (4711) and the formation of the second hole (4712) may be removed by applying plasma or a desmear chemical solution (in the case of FIG. 1).

The particulate by-products (953) or smear (955) generated during the formation of the first hole (4711) and the formation of the second hole (4712) may be removed and the polymer film (95) may be removed (in the case of FIG. 2).

Specifically, the cleaning operation may comprise: a desmear process of removing the particulate by-products (953) or smear (955) by applying plasma or a desmear chemical solution; and a protection-layer removal process of removing the polymer film (95) from the substrate that has undergone the desmear process.

The cleaning operation may be performed by applying a smear-removal process and a cleaning process.

The smear-removal process may be, for example, a wet desmear process.

The cleaning process may be a rinsing process and may be performed by applying a cleaning solution including an acid and/or a chemical.

The manufacturing method may further comprise an insulating-layer forming operation before the first processing operation.

The insulating-layer forming operation may comprise: a process of disposing, over the core substrate (10), a laminate of an insulating material and a polymer film (95); a process in which, under reduced-pressure lamination conditions, the insulating material flows under pressure applied by the polymer film (95) and is redistributed into voids inside the core substrate (10) and over a surface thereof; and a process of semi-curing or curing the insulating material. Through this, the workpiece may be provided in which an insulating layer (40) is disposed over the core substrate (10) and the polymer film (95) is disposed over the insulating layer (40). The insulating material may be an uncured sheet-shaped material, and, for example, an Ajinomoto build-up film may be applied, but the invention is not limited thereto.

The workpiece may be one in which an electrically conductive layer (30) and a core insulating layer (45) are disposed on the core substrate (10) (see (a) of FIG. 1).

As the core substrate, plate-shaped glass may be applied. Being a highly insulating material, it has the advantage of reducing concerns about parasitic element generation and, compared with substrates such as silicon, can be produced in a large area. Its characteristic as an insulator may bring the advantage of functioning more stably particularly when a high frequency is applied. For example, plate-shaped glass used in semiconductor processes may be applied. As examples, the core substrate may be borosilicate plate-shaped glass or alkali-free plate-shaped glass, but is not limited thereto.

The core substrate may be provided with core vias (through holes) that penetrate the plate-shaped glass in the thickness direction and/or cavities that penetrate the plate-shaped glass in the thickness direction or form a recessed surface. A through-electrode may be formed in the core via so that transmission of electrical signals in the up-down direction of the glass core is possible.

The core substrate may be 300 µm or more. The thickness of the core substrate may be 300 µm or more, 350 µm or more, 400 µm or more, 450 µm or more, or 500 µm or more. The thickness may be 2000 µm or less, 1800 µm or less, 1500 µm or less, 1200 µm or less, 1000 µm or less, 800 µm or less, or 700 µm or less. When a core substrate of such thickness is applied, a core substrate that plays a role as a support while ensuring durability at a certain level may be applied.

Formation of the electrically conductive layer may, for example, apply a process in which a copper layer is formed by a method such as copper plating. To efficiently carry out the copper plating, a seed layer or a sputtered layer may be applied.

An insulating layer may be disposed over the electrically conductive layer, and by repeating disposal of the electrically conductive layer and the insulating layer, redistribution lines (RDL) may be formed over or under the core substrate.

In this redistribution-line forming process, formation of via holes is required, and it is advantageous to apply the method of the embodiment particularly when forming deep via holes.

For example, the via hole of the embodiment may be formed over or under a cavity element (50).

A cavity element (50) refers to an electronic element disposed in a cavity of the core substrate (10). For example, a passive element such as an MLCC may be applied. For example, an active element such as a transistor may be applied. As the cavity element, a modular cavity element in which two or more passive and/or active elements are molded may be applied. As molding materials, a material comprising LCP (liquid crystal polymer), EMC (Epoxy Molding Compound), ABF (Ajinomoto Build-up Film), or MPI (Modified Polyimide) may be applied, but is not limited thereto.

When a cavity element is disposed in a cavity and an insulating layer is formed thereover, a distance to the cavity element may be greater than in ordinary cases. In such cases, the embodiment can be particularly usefully applied, although application of the embodiment is not limited thereto.

By the manufacturing method of via holes according to the embodiment, even deep via holes may be reliably manufactured with excellent accuracy.

Although the preferred embodiments of the present invention have been described in detail above, the scope of the present invention is not limited thereto, and various modifications and improved forms using the basic concepts of the present invention as defined in the following claims by those skilled in the art also fall within the scope of rights of the present invention.

What is claimed is:

1. A method of manufacturing via holes, comprising:
a first processing operation of applying a long-wavelength laser to a predetermined position of a workpiece to form a first hole; and
a second processing operation of applying a short-wavelength laser to the position where the first hole has been formed to form a second hole and thereby form a via hole;
wherein the workpiece comprises an insulating layer disposed over a core substrate, and
the via hole is formed in the insulating layer.

2. The method of claim 1,
wherein, in the first processing operation, a surface of the workpiece is the insulating layer, or a laminate in which a polymer film is stacked over the insulating layer.

3. The method of claim 1, further comprising a position-correction operation between the first processing operation and the second processing operation,
wherein the position-correction operation comprises checking an alignment mark, an overlay coupon pattern, or both disposed on the substrate, and matching the position of the first hole in the first processing operation with a center position of the second hole to be formed in the second processing operation.

4. The method of claim 1,
wherein a distance from a surface of the insulating layer to a bottom of the second hole is 60 µm or more.

5. The method of claim 1,
wherein a distance from a surface of the insulating layer to a bottom of the first hole is 40 µm or less.

6. The method of claim 2,
wherein a processing-protection layer is further disposed over the insulating layer, and the processing-protection layer is the polymer film.

7. The method of claim 1,
wherein a step (S) is present at a boundary between the first hole and the second hole.

8. The method of claim 1, further comprising an insulating-layer forming operation before the first processing operation,
wherein the insulating-layer forming operation comprises:
disposing, over the core substrate, a laminate of an insulating material and a polymer film;
under reduced-pressure lamination conditions, allowing the insulating material to flow under pressure applied by the polymer film so that the insulating material is redistributed into voids inside the core substrate and over a surface thereof; and
semi-curing or curing the insulating material;
thereby providing the workpiece in which an insulating layer is disposed over the core substrate and the polymer film is disposed over the insulating layer.

9. The method of claim 1, further comprising a cleaning operation after the second processing operation,
wherein the cleaning operation removes particulate by-products or smear generated during the formation of the first hole and the formation of the second hole.

10. The method of claim 9,
wherein the cleaning operation comprises:
a desmear process of removing the particulate by-products or smear by applying plasma or a desmear chemical solution; and
a protection-layer removal process of removing the processing-protection layer from the core substrate that has undergone the desmear process.
